(19) United States
(12) Patent Application Publication
(10) Pub. No.: US 2008/0117599 A1
(43) Pub. Date: May 22, 2008

(54) PORTABLE ELECTRONIC DEVICE

(75) Inventors: Motoki ENDO, Fussa-shi (JP); Osamu NAKAMURA, Kodaira-shi (JP); Masaharu SHIOYA, Akiruno-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 11/942,830

(22) Filed: Nov. 20, 2007

(30) Foreign Application Priority Data
Nov. 20, 2006 (JP) 2006-312666

(51) Int. Cl. H05K 7/20

(52) U.S. Cl. 361/705

(57) ABSTRACT

A portable electronic device includes a heat source which generates heat in association with generating, charging, or consuming electric power. A housing base member is disposed in proximity to the heat source, and a radiation film is disposed on at least a portion of an external surface of the housing base member. The radiation film has an emissivity that is higher than an emissivity of the housing base member.

### CROSS-REFERENCE TO RELATED APPLICATIONS

The present application is based upon and claims the benefit under 35 USC 119 of Japanese Patent Application No. 2006-312666 filed on Nov. 20, 2006, the entire contents of which are incorporated herein by reference.

### BACKGROUND OF THE INVENTION

1. Field of the Invention

The present invention relates to a portable electronic device.

2. Description of the Related Art

In recent years, the power consumption of portable electronic devices has tended to increase. For example, the power consumption of mobile personal computers has increased as the speeds of central processing units (CPU) thereof have increased. In addition, the power consumption of cellular phones has also tended to increase as the amount of information transmitted and received by the cellular phones has increased and as the number of functions thereof has also increased. Moreover, the power consumption of digital cameras has also tended to increase as the number of pixels that digital cameras are capable of photographing has increased and as the length of moving images that digital cameras are capable of recording has lengthened. Consequently, the amount of heat emitted from electric parts of these portable electronic devices has also tended to increase.

Several mechanisms for preventing the temperature of a device from rising have been proposed. For example, Japanese Patent Application Laid-Open Publication No. 2001-75677 discloses providing a fan motor to suck air into a laptop-type personal computer to cool the personal computer through a suction port, and enhancing the efficiency of the suction of the air by decreasing the loss of the sucked-in air due to a turbulent flow in the neighborhood of the suction port of the fan motor.

Moreover, Japanese Patent Application Laid-Open Publication No. 2000-31676 describes cooling an electronic device by using natural convection by a light metal having a high thermal conductivity without performing forced cooling with a fan.

Furthermore, Japanese Patent Application Laid-Open Publication No. 2000-253115 proposes radiating heat to the outside of an electronic device through a housing a magnesium alloy having a high thermal conductivity.

However, performing forced cooling with a fan has problems such as an installation location in order to reduce noises, electric power consumption, maintenance, and the like, which are related to the fan necessary to perform forced cooling. Moreover, performing cooling with a fan is not suitable for a mobile device having little extra space, such as a cellular phone or a digital camera.

Moreover, even if a metal having a high thermal conductivity is used as the housing of the portable electronic (or information) device, a user frequently feels discomfort when the user touches the housing because the heat radiation of the housing is not sufficient.

### SUMMARY OF THE INVENTION

It is, therefore, an object of the present invention to enhance heat radiation from a portable electronic device.

According to one aspect of the present invention, a portable electronic device is provided which includes: a heat source which generates heat in association with generating, charging, or consuming electric power; a housing base member disposed in proximity to the heat source; and a radiation film disposed on at least a portion of an external surface of the housing base member, wherein the radiation film having an emissivity that is higher than an emissivity of the housing base member.

### BRIEF DESCRIPTION OF THE DRAWINGS

The above and other objects, advantages and features of the present invention will become more fully understood from the detailed description given hereinbelow and the appended drawings which are provided for illustration only, and thus are not intended as a definition of the limits of the present invention. In the drawings:

FIG. 1 is a sectional view showing a portable electronic device 1, to which the present invention is applied;

FIG. 2 is a graph showing relationships between wavelengths of black body radiation and energy densities of the radiation;

FIG. 3 is a graph showing a relationship between temperatures (° C.) of a black body and heat radiation amounts (W) from the surface (10 cm²) of the black body when the ambient temperature is set at 23° C.;

FIG. 4 is a graph showing relationships between amounts of heat (W) emitted from a heater and surface temperatures (° C.) of a housing according to the existence of a radiation film 22 in case of using an Al plate as a housing base member 21;

FIG. 5 is a graph showing relations between amounts of heat (W) emitted from the heater and surface temperatures (° C.) of the housing according to the existence of the radiation film 22 in case of using a SUS plate as the housing base member 21;

FIG. 6A is a front view showing a first application of the portable electronic device of the present invention;

FIG. 6B is a rear elevation showing the first application of the portable electronic device of the present invention;

FIG. 6C is a sectional view taken along line VIC-VIC in FIG. 6B;

FIG. 7A is a front view showing an alternative structure of the first application of the portable electronic device of the present invention;

FIG. 7B is a rear elevation showing the alternative structure of the first application of the portable electronic device of the present invention;

FIG. 7C is a sectional view taken along line VIIC-VIIC in FIG. 7B;

FIG. 8A is a front side perspective view of a second application of the portable electronic device of the present invention;

FIG. 8B is a rear side perspective view of the second application of the portable electronic device of the present invention;

FIG. 9A is a front side perspective view of an alternative structure of the second application of the portable electronic device of the present invention;

FIG. 9B is a rear side perspective view of the alternative structure of the second application of the portable electronic device of the present invention;

FIG. 10 is a perspective view showing a third application of the portable electronic device of the present invention; and

FIG. 11 is a partially sectional view taken along line XI-XI in FIG. 10.

### DETAILED DESCRIPTION OF THE PREFERRED EMBODIMENTS

In the following, the best modes for implementing the present invention are described with reference to the attached drawings. While various technically preferable features are described below, the scope of the invention is not limited to the following embodiments and illustrated examples.

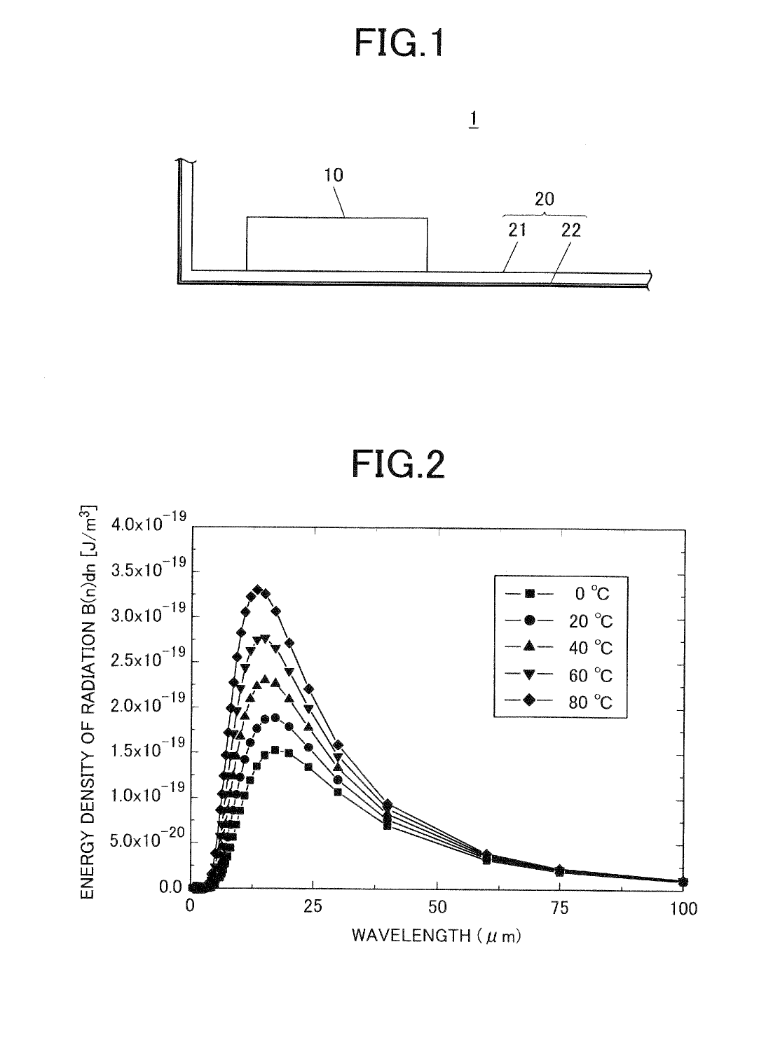

FIG. 1 is a sectional view of the principal part of a portable electronic device 1, to which the present invention is applied. As shown in FIG. 1, the portable electronic device 1 includes a heat source 10 and a housing 20. The heat source 10 is, for example, electronic parts that generate heat as they generate, charge, or consume electric power such as, for example, elements (e.g., a CPU) on a circuit board, and/or internal power sources, such as batteries.

The housing 20 includes a housing base member 21 and a radiation film 22 formed on the external surface of the housing base member 21

The housing base member 21 houses the heat source 10, (such as the circuit board controlling the electronic device 1 and the power source). It is preferable that the housing base member 21 be contacted to the internal heat source 10 in order to conduct heat from the internal heat source 10 to the housing base member 21 efficiently. It is preferable to use a metal having a high thermal conductivity as the housing base member 21 such as stainless steel (SUS). In particular, it is preferable to use a metallic material containing any of Al, Mg, and Ti as the principal component, such as an Al alloy, a Mg alloy, or a Ti alloy as the housing base member 21. Each one of pure metals such as Al, Mg and Ti is also preferably used. The use of such metallic materials enables the housing base member 21 to conduct the heat from the internal heat source 10 efficiently.

Because such metals each having a high thermal conductivity also have a high reflectance, the emissivity (=1-reflectance) of such materials is low. Consequently, using a metal having a high thermal conductivity for the housing base member 21 can prevent radiation from the external surface of the housing base member 21.

The properties of the housing base member 21 are examined in more detail below.

FIG. 2 is a graph showing the relationships between wavelengths (μm) and energy densities of radiation (J/m³) by a black body when the temperature of the black body (emissivity=1) is set at 0° C., 20° C., 40° C., 60° C., and 80° C. As shown in FIG. 2, the radiation wavelength range in the temperature range from 0° C. to 80° C. is from about 5 μm to about 100 μm, and the peaks of the energy densities of radiation are in the wavelength range from about 10 μm to about 25 μm. If the housing base member 21 were a black body, then it is conceivable that infrared rays in almost the same wavelength ranges as those shown in FIG. 2 would be generated from the housing base member 21 at surface temperatures of the housing base member 21 in the range from 0° C. to 80° C.

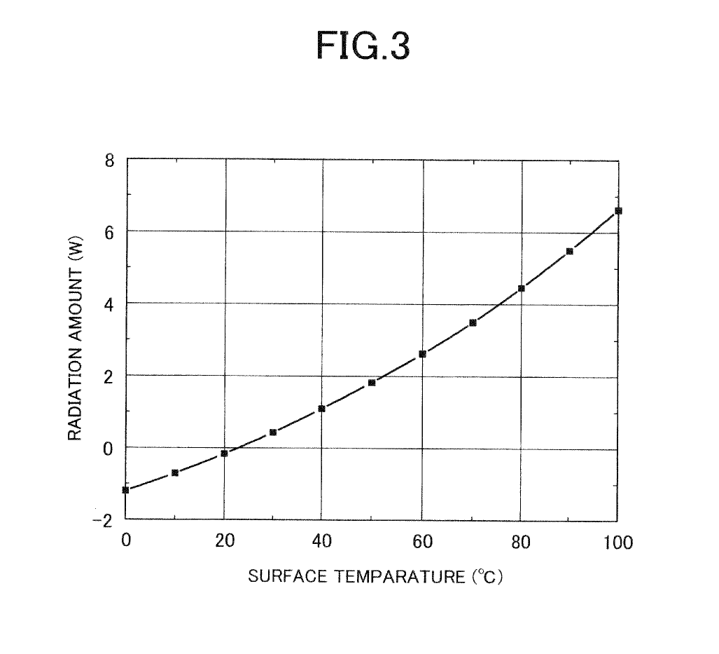

FIG. 3 is a graph showing a relationship between the surface temperatures (° C.) of a black body ranging from 0° C. to 100° C. and the heat radiation amounts (W) from 10 cm² of the surface of the black body when the ambient temperature is set at 23° C. For example, when the temperature of the black body is 50° C., the radiation amount from 10 cm² of the surface of the black body is a little less than 2 W. If the housing base member 21 were a black body, then it is conceivable that almost the same quantities of heat as the quantities shown in FIG. 3 would be radiated from the housing base member 21 at the surface temperatures of the housing base member 21 ranging from 0° C. to 100° C.

However, because the housing base member 21 is not a black body, the actual emissivity of the housing base member 21 is lower than 1.

In more detail, the emissivity on the longer wavelength side of a material is generally expressed by the following formula (I) based on the Hagen-Rubens' formula:

$$2 \sqrt{\frac{2 ɛω}{σ}} \qquad ( 1 )$$

where ∈ is a dielectric constant, ω is an angular frequency (ω=2πν), and σ is an optical conductivity (where ω=0).

As can be seen from formula (1), the emissivity of the material becomes smaller as the frequency ω becomes smaller, that is, as the wavelength λ (=c/ν) of the radiation becomes longer. Consequently, the longer the wavelength is in the wavelength range, the lower the emissivity is.

Moreover, as can also be seen from formula (1), the larger the optical conductivity a of the material is, the smaller the emissivity of the material becomes. Consequently, all of the metals and the conductors that have high optical conductivities have small emissivities.

The limit of the longest wavelength of the optical conductivity is equal to that of the electric conductivity. Consequently, all of the conductors having electrical conducting properties have low emissivities in a long wavelength range. Therefore, a radiation material in the long wavelength range is preferably an electrical insulator, in contrast to the material preferably used to form the housing base member 21.

According to the present embodiment, the radiation film 22 is provided on (for example, formed on) the external surface of the housing base member 21. The radiation film 22 may be a radiation material having a high emissivity (defined as an emissivity of 0.9 or more in the infrared region of wavelengths of 10 μm or more). The basic requirement of the radiation material having a high emissivity is that it be an electrical insulator. Therefore, any electrical insulator material that can easily be produced may be selected as the material for the radiation film 22. Various oxides such as SiO₂ and alumina (Al₂O₃), clay minerals, such as kaolin, and the like, can be used as the radiation material. For example, one or more of SiO₂, Al₂O₃, kaolin, RFeO₃ (R is a rare earth element), or the like, can be used.

Because the emissivity of a material having an electrical conducting property, such as an ordinary metal or graphite, which may appear to be black in the visible light region, is low in the long wavelength range, such a material cannot be used as the radiation material.

The radiation film 22 of SiO₂, Al₂O₃, or kaolin can be formed in a sheet by, for example, applying an emulsion liquid containing the high radiation material (e.g., SiO₂, Al₂O₃, or kaolin) onto a board drying the high radiation material on the board. The radiation film 22 can also be prepared by forming RFeO₃ (R is a rare earth element) on the housing base member 21 by a dip method using a nitrate thermal decomposition method.

It is preferable that the radiation film 22 be opaque, the wavelength range wherein the radiation film is opaque or not is 3000 nm to 50000 nm, in order to avoid the influences of the housing base member 21, which is made of a metallic material, on the radiation by the radiation film 22. For example, by forming Al₂O₃ as a porous body on the external surface of the housing base member 21 using a technique such as anodization, an opaque radiation film 22 can be formed. Alternatively, a cloth using thin glass fibers can be used as the radiation film 22.

Incidentally, if the radiation material is transparent, the wavelength range wherein the radiation material is transparent or not is 3000 nm to 50000 nm, then the thickness of the radiation film 22 is preferably made to be 100 μm or more in order to avoid the influences of the housing base member 21 on the radiation by the radiation film.

In the following, advantages achieved by providing the radiation film 22 are shown by describing a specific example.

### EXAMPLE

### 1. Housing Base Member

A housing base member 21 having the dimensions 87 mm×54 mm×9 mm was made of an Al plate or a SUS plate having a thickness of 1.5 mm, and a heating element of dimensions 48 mm×33 mm×4.5 mm having a heater therein as the heat source 10 was housed in the housing base member 21.

### 2. Radiation Film

An emulsion liquid containing SiO₂, Al₂O₃ and kaolin as a high radiation material (having an emissivity of 0.9 or more in the infrared region of wavelengths of 10 μm or more) was applied on the housing base member 21, and the emulsion liquid was dried to form a sheet-shaped radiation film 22 on the housing base member 21.

### 3. Measurement of Surface Temperature of Housing

The surface temperature (° C.) of the housing was measured at when various electric powers (W) were applied to the heater.

### 4. Results

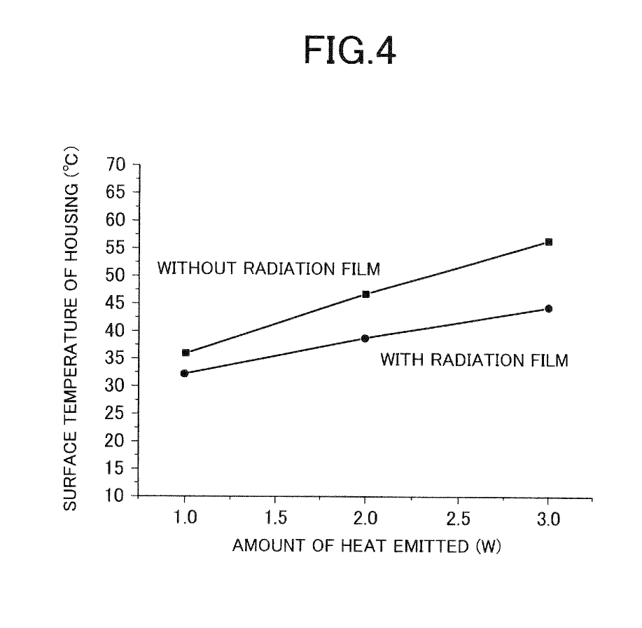

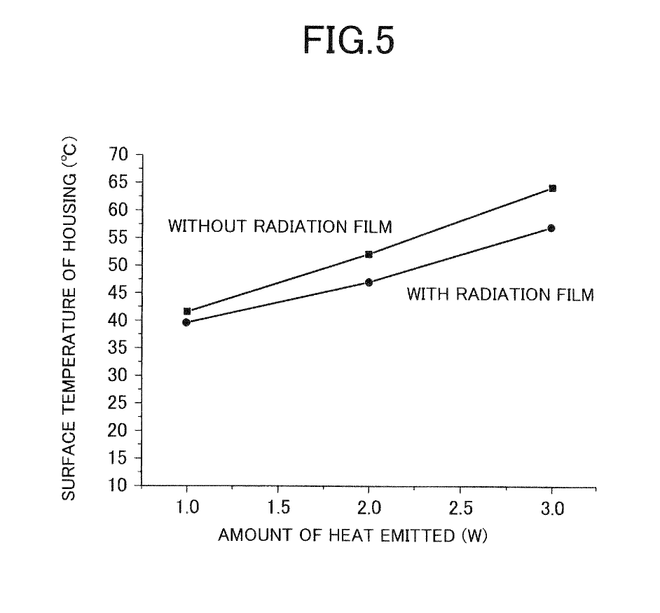

FIG. 4 is a graph showing measured relationships between the amounts of heat (W) emitted from the heater and the surface temperatures (° C.) of the housing when the housing 20 included an Al housing base member 21 and a radiation film 22 (lower line), and when the housing included only an Al housing base member without a radiation film (upper line). FIG. 5 is a graph showing measured relationships between the amounts of heat (W) emitted from the heater and the surface temperatures (° C.) of the housing when the housing 20 included an SUS housing base member 21 and a radiation film 22 (lower line), and when the housing included only an SUS housing base member without a radiation film (upper line). The amounts of heat (W) emitted from the heaters are electric powers here.

If the Al plate was used as the housing base member 21, the surface temperature was 47° C. at the electric power of 2 W if no radiation film 22 was provided, whereas the surface temperature lowered to 39° C. at the electric power of 2 W if the radiation film 22 was provided.

On the other hand, if the SUS plate was used as the housing base member 21, the surface temperature was 52° C. at the electric power of 2 W if no radiation film 22 was provided, whereas the surface temperature was lowered to 47° C. at the electric power of 2 W if the radiation film 22 was provided.

Accordingly, with the structure of the present embodiment, the heat from the heat source 10 can be conducted by the housing base member 21 and can be efficiently emitted by radiation from the radiation film 22 by using a material having a high thermal conductivity as the housing base member 21, and by using the radiation film 22 made of a radiation material having a high emissivity (an emissivity of 0.9 or more in the infrared region of wavelengths of 10 μm or longer) on the external surface of the housing base member 21.

Incidentally, a fuel cell device may be used as the internal power source of the portable electronic device 1 in place of the battery. Although the amounts of heat emitted from the fuel cell device increases more than that of the conventional battery at the time of power generation by the fuel cell device, a temperature rise of the housing 20 can be suppressed because the radiation film 22 is formed on the external surface of the housing base member 21.

Moreover, instead of a metal, a resin, such as a plastic, may be used as the housing base member 21, and the radiation film 22 may be formed on the external surface of the housing base member 21 using the resin such as the plastic.

### [First Application]

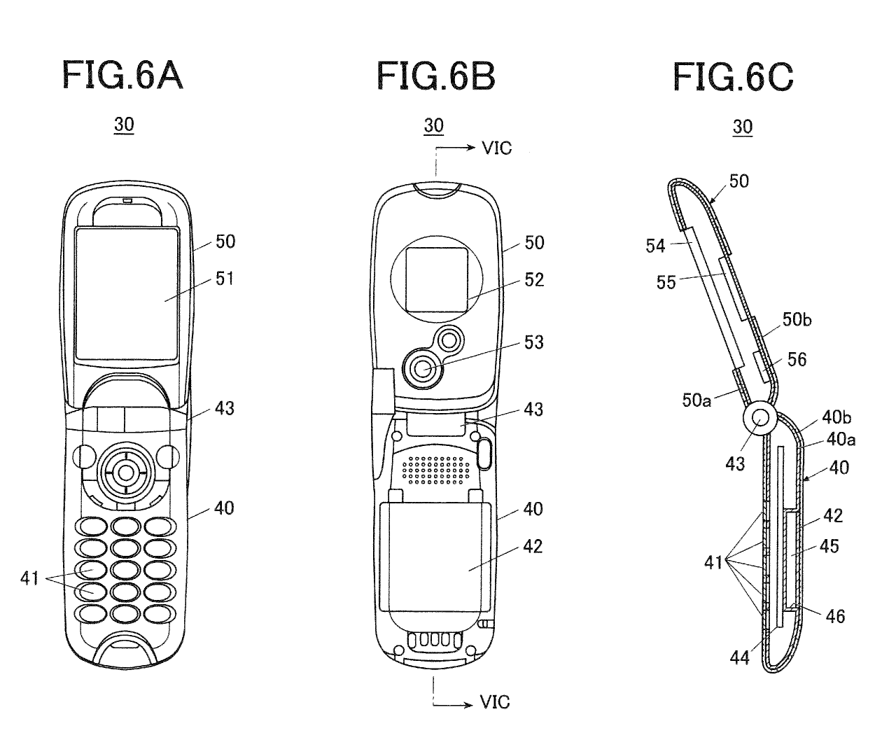

FIGS. 6A-6C are three orthographic views showing a cellular phone 30 as a first application of the portable electronic device to which the present invention is applied. FIG. 6A is the front view, FIG. 6B is the rear elevation, and FIG. 6C is a sectional view taken along a line VIC-VIC in FIG. 6B. The cellular phone 30 includes a first housing 40 and a second housing 50, and the first housing 40 and the second housing 50 are coupled with each other through a hinge section 43 so as to be foldable with respect to each other.

Operation keys 41 are provided on the front surface of the first housing 40 (the surface that is opposed to the second housing 50 when the first and second housings are folded together). A main board 44, a keypad (not shown), and the like, are housed inside the first housing 40.

Moreover, a concave portion 46, in which a battery pack 45 as the internal power source of the cellular phone 30 is housed, is formed in the back surface of the first housing 40, and a battery cover 42 is provided to cover the concave portion 46 (e.g., when the battery pack is housed therein).

The second housing 50 is provided with liquid crystal display sections 51 and 52, and a lens section 53 for a built-in camera. Moreover, liquid crystal display apparatuses 54 and 55 and a lens driving section 56 are housed inside the second housing 50.

The first housing 40 and the second housing 50 include housing base members 40a and 50a, respectively, all or a part of each of which is thin-walled and made of a metal having a high thermal conductivity, and radiation films 40b and 50b respectively formed on the external surfaces of the housing base members 40a and 50a. The radiation films 40b and 50b are shown only in FIG. 6C. Moreover, the radiation film 40b is formed on substantially the whole external surface of the outside of the first housing 40, except for the portions where the operation keys 41 are provided, and the radiation film 50b is formed on substantially the whole surface of the outside of the second housing 50, except for the portions where the liquid display sections 51 and 52 and the lens section 53 of the built-in camera are provided.

The housing base members 40a and 50a and the radiation films 40b and 50b can be formed from materials that are the same as or similar to the materials used to form the housing base member 21 and the radiation film 22 as described above, and the radiation films 40b and 50b can be formed on the housing base members 40a and 50a in a manner that is the same as or similar to the way in which the radiation film 22 is formed on the housing base member 21 as described above. In this regard, the housing base members 40a and 50a and the radiation films 40b and 50b can be formed of the same or similar materials, however, can also be formed of different materials.

With this structure of the first housing 40 and the second housing 50, heat from the main board 44, the liquid display apparatuses 54 and 55, the battery pack 45, and the like, can be efficiently radiated from the cellular phone 30.

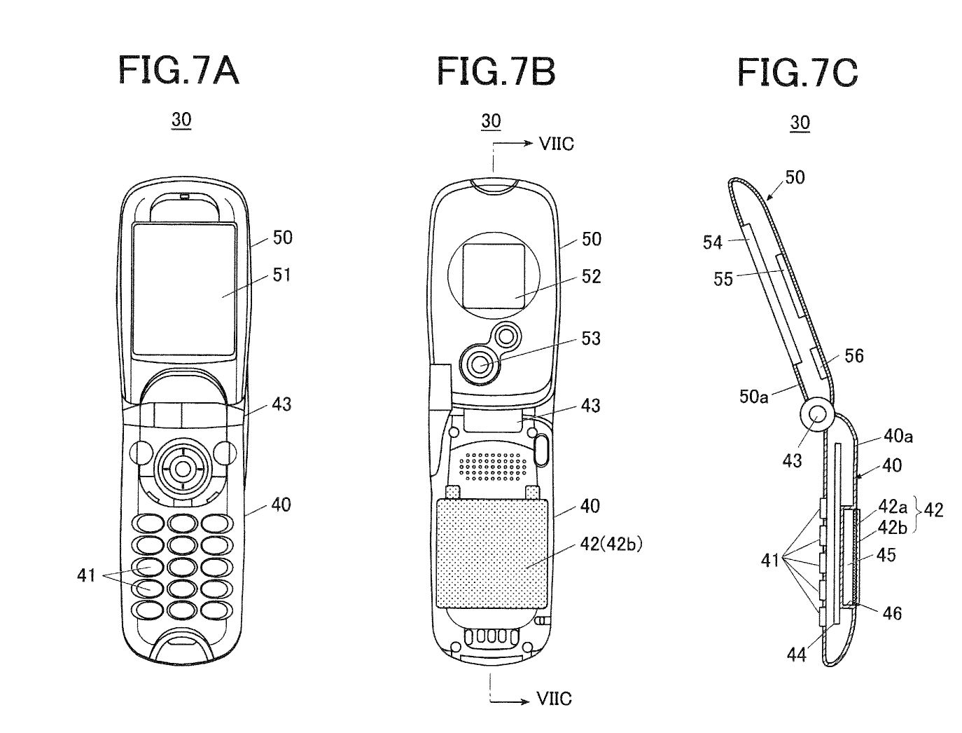

Incidentally, the radiation film may be formed on only a part of the external surfaces of the housing base members 40a and 50a. For example, as shown in FIGS. 7A-7C, the battery cover 42 may include base member 42a (as a removable portion of the housing base member 40a) and a radiation film 42b formed on the housing base member 42a, and the radiation film 42b may be the only radiation film provided to the cellular phone 30 (that is, no radiation film is provided on the housing base members 40a and 50a except at the base member 42a in this alternative structure). The radiation of heat from the battery pack 45, which has the largest amounts of heat emitted from the components of the cellular phone 30, can still be efficiently performed in this structure in which the radiation film 42b is formed only on the housing base member 42a of the battery cover 42. With this structure, moreover, the amount of the radiation film becomes the minimal, whereby the amount of material needed to form the radiation film on the cellular phone 30 can be reduced.

### [Second Application]

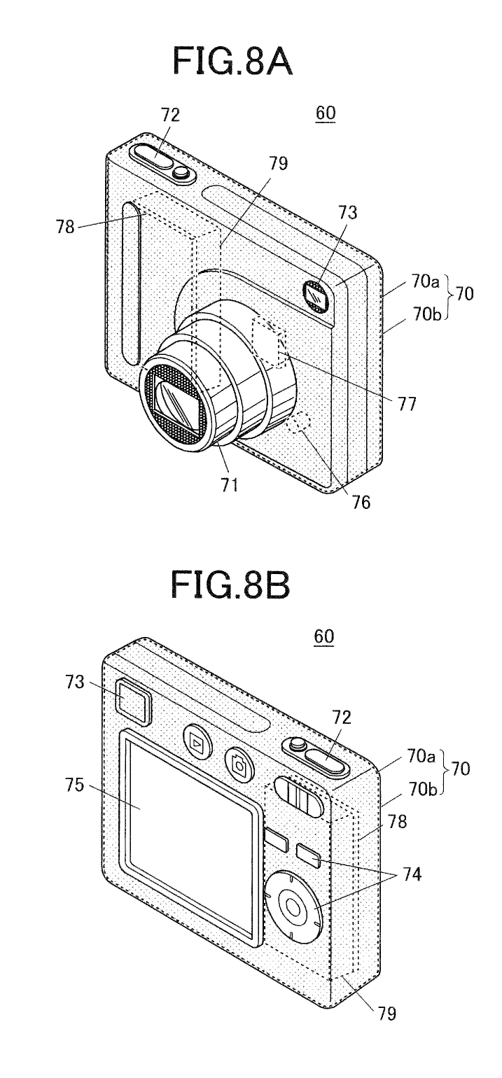

FIGS. 8A and 8B are perspective views showing a digital camera 60 as a second application of the portable electronic device to which the present invention is applied. FIG. 8A shows the front side of the digital camera 60, and FIG. 8B shows the back side of the digital camera 60.

The digital camera 60 has a housing 70. A lens 71 projects from the front section of the housing 70. A shutter key 72 and a finder 73 are provided at the upper part of the housing 70, and the finder 73, operation keys 74, a liquid crystal display section 75, and the like, are provided at the rear surface of the housing 70. A housing section (not shown) of the lens 71, a lens driving mechanism 76, an imaging device 77, a control circuit 78, an internal power source 79, and the like, which are heat sources, are housed inside the housing 70. Incidentally, the lens driving mechanism 76 is housed in the neighborhood of the lens 71.

The housing 70 includes a housing base member 70a, all or a part of which is thin-walled and made of a metal having a high thermal conductivity, and a radiation film 70b provided on the external surface of the housing base member 70a. The radiation film 70b is provided on substantially the whole external surface of the housing base member 70a, except for the parts where the lens 71, the shutter key 72, the finder 73, the operation keys 74, the liquid display section 75, and the like, are provided.

The housing base member 70a and the radiation film 70b can be formed from materials that are the same as or similar to the materials used to form the housing base member 21 and the radiation film 22 as described above, and the radiation film 70b can be formed on the housing base member 70a in a manner that is the same as or similar to the way in which the radiation film 22 is formed on the housing base member 21 as described above. In this regard, the housing base member 70a and the radiation film 70b can be formed of the same or similar materials, however, can also be formed of different materials.

With the structure of the housing base member 70, the heat from the lens driving mechanism 76, the imaging apparatus 17, the control circuit 78, the internal power source 79, and the like, can be efficiently radiated from the digital camera 60.

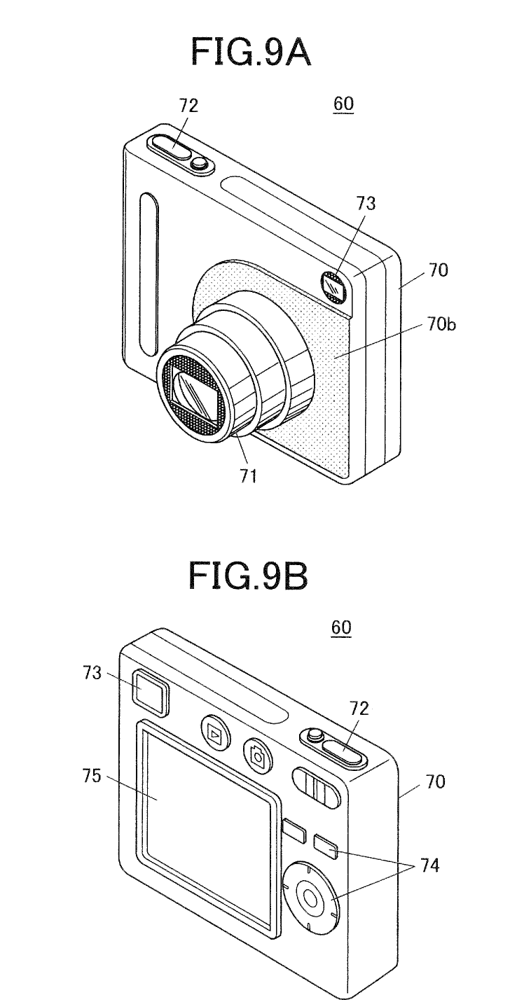

Incidentally, as shown in FIGS. 9A and 9B, the radiation film 70b may be provided on the housing base member 70a only at a portion of the housing 70 at the periphery of the lens 71. In this structure, the remaining portion of the housing 70 is formed by only the housing base member 70a. In other words, in this alternative structure, the radiation film 70b is provided only in the neighborhood of the part where the lens driving mechanism 76 is built in. By providing the radiation film 70b only in the neighborhood of the part where the lens driving mechanism 76 is built in, the heat from the lens driving mechanism 76, which radiates a large amount of heat, can still be efficiently radiated. With this structure, moreover, the amount of the radiation film becomes minimal, whereby the amount of the material needed to form the radiation film on the digital camera 60 can be reduced.

### [Third Application]

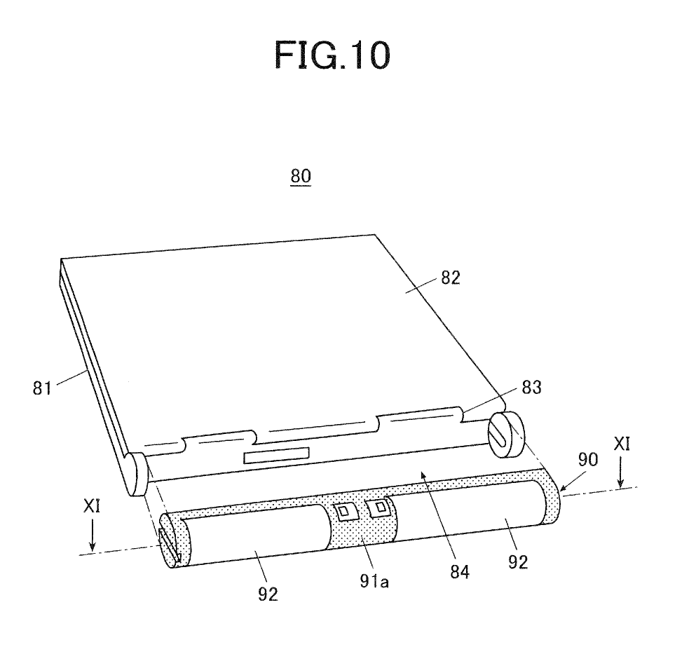

FIG. 10 is a perspective view showing a notebook personal computer 80 as a third application of the portable electronic device to which the present invention is applied.

The personal computer 80 includes a lower housing 81, an upper housing 82, a hinge 83 which couples the lower housing 81 and the upper housing 82, and a power source section go. The lower housing 81 and the upper housing 82 are configured to be capable of being folded together (i.e., in a stack) using the hinge 83.

The lower housing 81 has an arithmetic processing circuit including a CPU, a random access memory (RAM), a read only memory (ROM), and other electric parts therein, and a keyboard (not shown) is provided on the surface thereof opposed to the upper housing 82. The upper housing 82 is provided with a liquid crystal display (not shown) on the surface thereof opposed to the lower housing 81.

An installing section 84 is formed at the rear part of the hinge 83 on the lower housing 81. A power source section 90 is freely attachable to and detachable from the installing section 84. Thus, the upper housing 82 and lower housing 81, including the hinge 83 and installing section 84, form a main body that the power source section 90 is attachable to and detachable from.

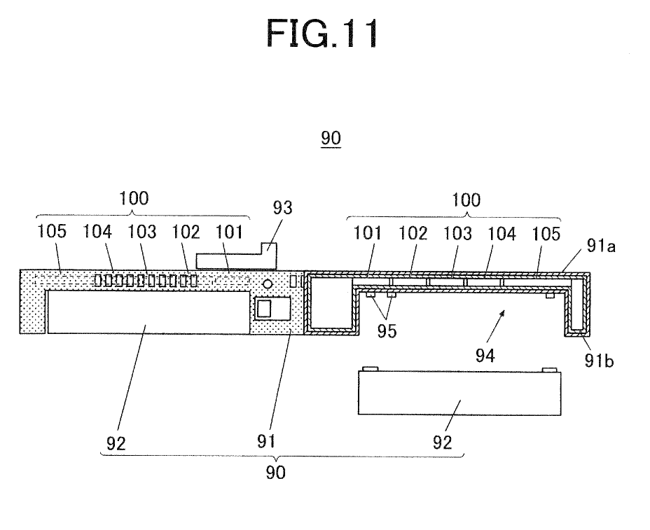

FIG. 11 is a partial sectional view taken along line XI-XI in FIG. 10, in which only the right half portion of the main body section 91 is shown by a cutaway view. The power source section 90 includes a main body section 91 and fuel cartridges 92, which are freely attachable to and detachable from the main body section 91 at installing sections 94 of the main body 91. An interface 93 to supply electric power to the lower housing 81 when the power source section 90 is connected with the lower housing 81 is provided on the surface of the main body section 91 that is opposed to the lower housing 81. Moreover, interfaces 95 to be connected to the fuel cartridges 92 are formed on the installing sections 94.

Two fuel cell devices 100 are provided in the housing of the main body section 91. One fuel cell device 100 is provided for each of the installing sections 94. The fuel cell device 100 is a device which converts reaction energy of fuel and air into electric power energy, and includes, for example, a pump 101 which supplies fuel and water from inside one of the fuel cartridges 92, a vaporizer 102 which vaporizes the fuel, a reformer 103 which generates a gas containing hydrogen (reformed gas) by a reforming reaction of the fuel, a carbon monoxide remover 104 which removes carbon monoxide, which is a by-product of the reforming reaction, a power generation cell 105 which converts reaction energy of the hydrogen in the reformed gas and oxygen in the air into electric power energy, and the like.

The housing of the main body section 91 is made by forming a radiation film 91b on the external surface of a housing base member 91a, all or a part of which is thin-walled and made of a metal having a high thermal conductivity.

The housing base member 91a and the radiation film 91b can be formed from materials that are the same as or similar to the materials used to form the housing base member 21 and the radiation film 22 as described above, and the radiation film 91b can be formed on the housing base member 91a in a manner that is the same as or similar to the way in which the radiation film 22 is formed on the housing base member 21 as described above. In this regard, the housing base member 91a and the radiation film 91b can be formed of the same or similar materials, however, can also be formed of different materials.

With this structure of the housing main body section 91, the heat from the fuel cell devices can be efficiently radiated.

The cellular phone 30, the digital camera 60, and the notebook personal computer 80 have been described above as portable electronic devices to which the present invention is applicable. The devise to which the present invention is applicable are not limited to such devices. For example, the present invention can be applied to other portable electronic devices, such as a personal digital assistant (PDA), an electronic personal organizer, a wrist watch, an electronic cash register, and a projector.

Incidentally, fuel cell devices may be used as the internal power sources of the cellular phone 30 and the digital camera 60. Although the amounts of heat emitted from the fuel cell device at the time of power generation increases more than that of a conventional battery, the rise of the temperature of the housing can be suppressed because according to the present invention a radiation film is formed on the external surface of a housing base member of the housing.

Although various exemplary embodiments have been shown and described, the invention is not limited to these embodiments. Therefore, the scope of the invention is intended to be limited solely by the scope of the claims that follow.

What is claimed is:

1. A portable electronic device, comprising:
a heat source which generates heat in association with generating, charging or consuming electric power;
a housing base member disposed in proximity to the heat source; and
a radiation film disposed on at least a portion of an external surface of the housing base member,
wherein the radiation film has an emissivity which is higher than an emissivity of the housing base member.

2. The portable electronic device according to claim 1, wherein the housing base member encloses the heat source.

3. The portable electronic device according to claim 1, wherein:
the heat source comprises a battery;
the portable electronic device includes a concave portion adapted to house the battery;
the housing base member includes a battery cover to cover the concave portion; and
the radiation film is formed on an external surface of the battery cover.

4. The portable electronic device according to claim 3, wherein the radiation film is only provided on the housing base member at the battery cover.

5. The portable electronic device according to claim 1, wherein:
the heat source comprises a lens driving mechanism provided inside the housing base member, and
the radiation film is provided on the housing base member in a vicinity of the lens driving mechanism.

6. The portable electronic device according to claim 5, wherein the radiation film is only provided on the housing base member in the vicinity of the lens driving mechanism.

7. The portable electronic device according to claim 1, wherein the radiation film covers substantially all of the housing base member.

8. The portable electronic device according to claim 1, wherein the housing base member is made of a metal.

9. The portable electronic device according to claim 1, wherein the housing base member consists essentially of a material selected from the group consisting of Al, Mg, and Ti.

10. The portable electronic device according to claim 1, wherein the housing base member is made of an alloy having one of Al, Mg and Ti as its principal component.

11. The portable electronic device according to claim 1, wherein the radiation film has an emissivity of at least 0.9 in an infrared region having a wavelength of 10 μm or longer.

12. The portable electronic device according to claim 1, wherein the heat source comprises a fuel cell device.

13. The portable electronic device according to claim 1, wherein the portable electronic device comprises a main body and a power source section, and
wherein the power source section comprises the heat source, the housing base member, and the radiation film on the housing base member.

14. The portable electronic device according to claim 13, wherein the power source section is attachable to and detachable from the main body.

15. The portable electronic device according to claim 13, wherein the heat source comprises a fuel cell device.
